(19) United States
(12) Patent Application Publication
(10) Pub. No.: US 2025/0029835 A1
(43) Pub. Date: Jan. 23, 2025

(54) INTEGRATED PLASMA CLEAN AND DIELECTRIC PASSIVATION DEPOSITION PROCESSES

(71) Applicant: Applied Materials, Inc., Santa Clara, CA (US)

(72) Inventors: Ryan Ley, Mountain View, CA (US); Archana Kumar, Mountain View, CA (US); Michel El Khoury Maroun, Mountain View, CA (US); Benjamin D. Briggs, Merrimack, NH (US)

(73) Assignee: Applied Materials, Inc., Santa Clara, CA (US)

(21) Appl. No.: 18/770,960

(22) Filed: Jul. 12, 2024

Related U.S. Application Data
(60) Provisional application No. 63/527,638, filed on Jul. 19, 2023.

(51) Int. Cl. H01L 21/02; C23C 16/34; C23C 16/50; H01J 37/32

(52) U.S. Cl. CPC H01L 21/0254; C23C 16/34; C23C 16/50; H01J 37/32899; H01L 21/02274; H01L 21/02389; H01J 2237/332; H01J 2237/335

(57) ABSTRACT

Exemplary semiconductor processing methods may include performing a treatment operation on a substrate housed within a first processing region of a first semiconductor processing chamber. The methods may include providing a nitrogen-containing precursor to the first processing region. The methods may include forming plasma effluents of the nitrogen-containing precursor. The methods may include contacting the substrate with the plasma effluents of the nitrogen-containing precursor. The contacting may nitride a surface of the substrate. The methods may include transferring the substrate from the first processing region of the first semiconductor processing chamber to a second processing region of a second semiconductor processing chamber. The methods may include providing one or more deposition precursors to the second processing region. The methods may include contacting the substrate with the one or more deposition precursors. The contacting may deposit a layer of dielectric material on the substrate.

### CROSS-REFERENCE TO RELATED APPLICATIONS

This application claims the benefit of, and priority to U.S. Provisional Application Ser. No. 63/527,638, filed Jul. 19, 2023, which is hereby incorporated by reference in its entirety for all purposes.

### TECHNICAL FIELD

The present technology relates to semiconductor processing and materials. More specifically, the present technology relates to formation processes and materials for high electron-mobility transistors.

### BACKGROUND

Semiconductor structures containing metal-nitrides are finding increased importance in the development and fabrication of short wavelength light emitting diodes (LEDs), laser diodes (LDs), and high electron-mobility transistors (HEMTs). As one example, HEMTs may be formed as a field-effect transistor incorporating a junction between two materials with different band gaps as the channel instead of a doped region (as is generally the case for a metal-oxide-semiconductor field-effect transistor (MOSFET)). Recently, gallium nitride HEMTs have attracted attention due to their high-power performance. While there have been considerable developments to HEMTs and to gallium nitride HEMTs, HEMTs in general may still encounter defects that lead to reduced performance.

Thus, there is a need for improved systems and methods that can be used to produce high quality devices and structures. These and other needs are addressed by the present technology.

### SUMMARY

Exemplary semiconductor processing methods may include performing a treatment operation on a substrate housed within a first processing region of a first semiconductor processing chamber. The treatment may include providing a nitrogen-containing precursor to the first processing region of the first semiconductor processing chamber, forming plasma effluents of the nitrogen-containing precursor, and contacting the substrate with the plasma effluents of the nitrogen-containing precursor. The contacting may nitride a surface of the substrate. The methods may include providing a nitrogen-containing precursor to the first processing region of the first semiconductor processing chamber. The methods may include forming plasma effluents of the nitrogen-containing precursor. The methods may include contacting the substrate with the plasma effluents of the nitrogen-containing precursor. The contacting may nitride a surface of the substrate. The methods may include transferring the substrate from the first processing region of the first semiconductor processing chamber to a second processing region of a second semiconductor processing chamber. The methods may include providing one or more deposition precursors to the second processing region of the second semiconductor processing chamber. The methods may include contacting the substrate with the one or more deposition precursors. The contacting may deposit a layer of dielectric material on the substrate.

In some embodiments, the nitrogen-containing precursor comprises diatomic nitrogen (N₂) or ammonia (NH₃). The methods may include providing a hydrogen-containing precursor to the first processing region of the first semiconductor processing chamber with the nitrogen-containing precursor. The hydrogen-containing precursor may be or include diatomic hydrogen (H₂). The substrate may include a layer of nitrogen-containing material. Prior to contacting the substrate with plasma effluents of the nitrogen-containing precursor, the substrate may be contaminated with oxygen, carbon, or nitrogen-vacancy defects. The methods may include forming plasma effluents of the one or more deposition precursors. The layer of dielectric material may include a silicon-and-nitrogen-containing material, a silicon-and-oxygen-containing material, an aluminum-and-nitrogen-containing material, or an aluminum-and-oxygen-containing material. The layer of dielectric material may be deposited via chemical vapor deposition (CVD), physical vapor deposition (PVD), or atomic layer deposition (ALD). A vacuum environment may be maintained while transferring the substrate from the first processing region of the first semiconductor processing chamber to the second processing region of the second semiconductor processing chamber.

Some embodiments of the present technology may encompass semiconductor processing methods. The methods may include performing a treatment operation on a substrate housed within a first processing region of a first semiconductor processing chamber. The substrate may include a layer of nitrogen-containing material. The treatment may include providing an aluminum-containing precursor to a first processing region of a first semiconductor processing chamber, wherein, and contacting the substrate with the aluminum-containing precursor. The contacting may form a layer of aluminum-and-nitrogen-containing material on the substrate. The methods may include transferring the substrate from the first processing region of the first semiconductor processing chamber to a second processing region of a second semiconductor processing chamber. The methods may include providing one or more deposition precursors to the second processing region of the second semiconductor processing chamber. The methods may include depositing a layer of passivation material on the substrate.

In some embodiments, the substrate may include an aluminum-gallium-and-nitrogen-containing material. The aluminum-containing precursor may be or include trimethylaluminum (TMA). The first processing region of the first processing chamber may be maintained plasma-free. The one or more deposition precursors may include an aluminum-containing precursor, a silicon-containing precursor, a nitrogen-containing precursor, an oxygen-containing precursor, or combinations thereof. The passivation material may include a dielectric material.

Some embodiments of the present technology may encompass semiconductor processing system. The systems may include a first semiconductor processing chamber defining a first processing region. The first semiconductor processing chamber may be operable to perform a treatment operation on a substrate. The systems may include a second semiconductor processing chamber defining a second processing region. The second semiconductor processing chamber may be operable to perform a dielectric material deposition operation on the substrate. The systems may include a mainframe connected to both the first semiconductor processing chamber and the second semiconductor processing chamber. The mainframe may be operable to transfer the substrate between the first processing region and the second processing region without breaking a vacuum environment.

In some embodiments, the first semiconductor processing chamber may further be operable to perform a surface nitridation operation on the substrate. The dielectric material deposition operation may form a silicon-and-nitrogen-containing material, a silicon-and-oxygen-containing material, an aluminum-and-nitrogen-containing material, or an aluminum-and-oxygen-containing material on the substrate. The mainframe may be operable to receive the substrate prior to providing the substrate to the first processing region of the first semiconductor processing chamber. The substrate received in the mainframe may be contaminated with oxygen, carbon, or nitrogen-vacancy defects.

Such technology may provide numerous benefits over conventional systems and techniques. For example, the present technology may remove surface contamination from substrates or layers on substrates. Additionally, the present technology may form passivation material, such as dielectric material, on the surfaces without contamination to achieve increased performance in final structures or devices. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows selected operations in a method of forming a light-emitting diode structure according to some embodiments of the present technology.

FIGS. 3A-3D illustrate a schematic view of a device developed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

HEMTs are field-effect transistors incorporating a junction between two materials with different band gaps as the channel instead of a doped region (as is generally the case for a MOSFET). HEMTs may be used in integrated circuits as digital on-off switches. HEMTs have high gain, which makes them useful as amplifiers. HEMTs also have high switching speeds, which are achieved because the main charge carriers in modulation-doped field effect transistors (MODFETs) are majority carriers, and minority carriers are not significantly involved. Many conventional HEMTs are formed with a passivation layer overlying a metal nitride layer, such as a gallium nitride layer. The passivation layer may serve to improve performance of final structures or devices. However, prior to forming the passivation layer, the structures are commonly exposed to atmosphere and oxidation occurs. If contamination from the oxidation is left untreated, contaminants may degrade performance of the final structures or devices. In order to remove contaminants prior to deposition of the passivation material, conventional technologies have utilized wet clean operations. However, these wet clean operations are insufficient as the surface will re-oxidize before the passivation deposition. Other conventional technologies have attempted to perform the cleaning and passivation deposition in a single chamber, but this too has been insufficient.

The present technology may overcome issues associated with conventional technologies by performing a plasma-enhanced treatment to clean or remove surface contamination. The plasma-enhanced treatment may also nitride the surface to allow for better passivation deposition. Additionally, the present technology performs the operations without breaking a vacuum environment. Accordingly, the present technology minimizes and/or avoids any possibility of re-oxidation. Although the remaining disclosure will routinely identify specific HEMT materials and processes utilizing the disclosed technology, it will be readily understood that the systems and methods are equally applicable to a variety of materials and processes as may occur for producing semiconductor structures. Accordingly, the technology should not be considered to be so limited as for use with HEMT processes alone. After discussing an exemplary processing system that may be used according to some embodiments of the present technology, methods for producing high-quality structures will be described.

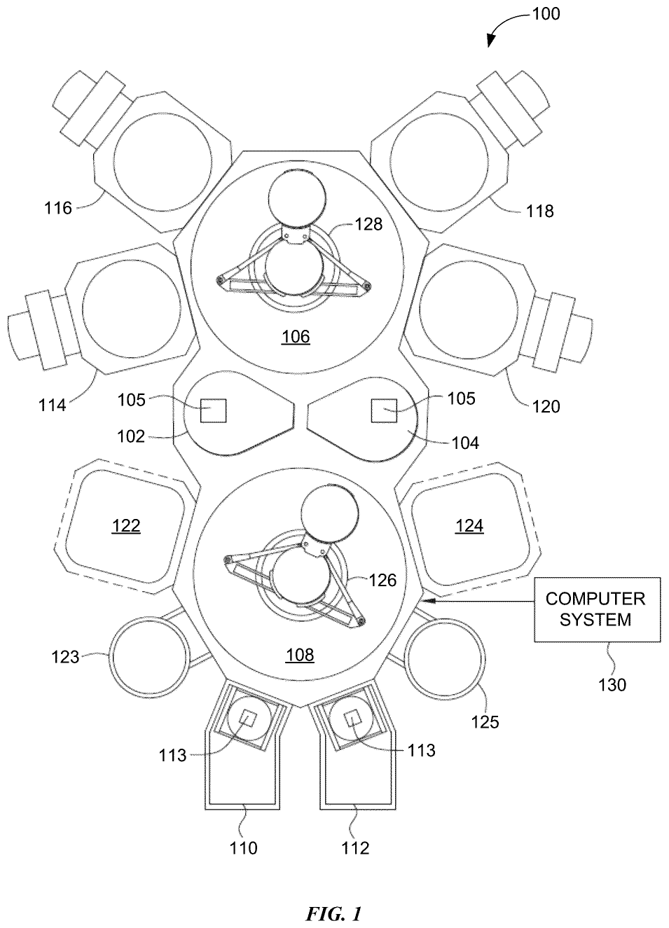

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, semiconductor processing chambers 114, 116, 118, 120, 122, and 124, preheating chambers 123 and 125, and robots 126 and 128. The single wafer load locks 110 and 112 may include heating elements 113 and may be attached to the buffer chamber 108. The semiconductor processing chambers 114, 116, 118, and 120 may be attached to the transfer chamber 106. The semiconductor processing chambers 122 and 124 may be attached to the buffer chamber 108. Two substrate transfer platforms 102 and 104, which may be referred to as a mainframe, may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the semiconductor processing chambers 114, 116, 118, 120, 122, and 124 may be configured to perform one or more process steps in the fabrication of a semiconductor structure. More specifically, the semiconductor processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

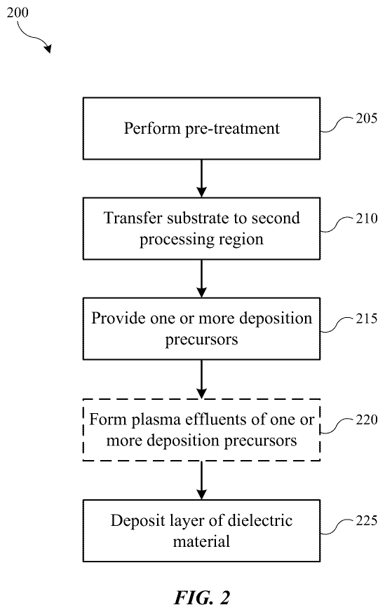

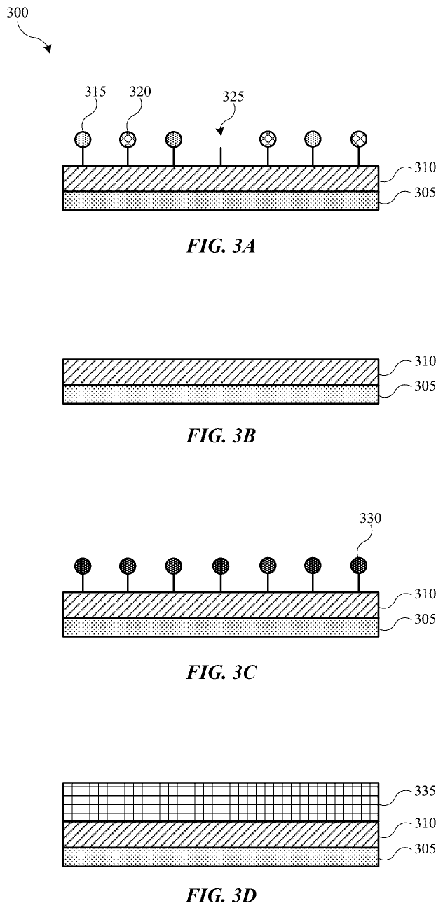

FIG. 2 illustrates selected operations of a semiconductor processing method 200. Method 200 may include one or more operations prior to the initiation of the method, including front end processing, deposition, etching, polishing, cleaning, or any other operations that may be performed prior to the described operations. For example, in some embodiments a degas operation may be performed on a substrate, such as silicon, germanium or germanium-containing, or sapphire substrate, to prepare the substrate for method 200. The method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 200 describes operations shown schematically in FIGS. 3A-3D, the illustrations of which will be described in conjunction with the operations of method 200. It is to be understood that FIGS. 3A-3D illustrate only a partial schematic view, and a substrate may contain any number of sections having aspects as illustrated in the figure, as well as alternative structural aspects that may still benefit from aspects of the present technology.

Method 200 may involve optional operations to develop the structure to a particular fabrication operation. As illustrated in FIGS. 3A-3D, a substrate 305 may be used to facilitate a layer of material being formed or grown overlying the substrate 305. Substrate 305 may be any substrate on which structures may be formed, such as silicon-containing materials, aluminum materials, including sapphire, gallium-containing materials, or any other materials as may be used in semiconductor or display fabrication. Substrate 305 may have a substantially planar surface or an uneven surface in embodiments. The substrate 305 may have various dimensions, such as 200 mm or 300 mm diameter wafers, as well as rectangular or square panels. The substrate 305 may be cleaned or processed in preparation for depositing one or more layers of material on the substrate for producing a structure, such as an LED, for example, although any number of other semiconductor structures may similarly benefit from aspects of the present technology.

In embodiments, a layer of nitrogen-containing material 310 may be formed overlying the substrate 305. The layer of nitrogen-containing material 310 may be or include, but is not limited to, a gallium-and-nitrogen-containing material such as gallium nitride (GaN), niobium nitride (NbN), hafnium nitride (HfN), aluminum nitride (AlN), aluminum gallium nitride (AlGaN). While specific metal-and-nitrogen-containing materials have been set forth, it is also contemplated that metal-and-oxygen-containing materials and metal-oxygen-and-nitrogen-containing materials may benefit from the present technology. In embodiments, the layer of nitrogen-containing material 310 may be, include, consist, or consist essentially of AlGaN. Further, in embodiments, the layer of AlGaN of material may be deposited on a silicon substrate, and the layer of AlGaN of material may be deposited on the silicon substrate through, for example, plasma vapor deposition or any other deposition method.

In embodiments, substrate 305 and the layer of nitrogen-containing material 310 may be exposed to atmosphere, which may result in contamination of a surface of the substrate 305 and/or a surface the layer of nitrogen-containing material 310. As illustrated in FIG. 3A, oxygen contamination 315, carbon contamination 320, and/or nitrogen-vacancy defects 325 may be present on the surface of the substrate 305 and/or the surface of the layer of nitrogen-containing material 310. If left untreated, oxygen contamination 315, carbon contamination 320, and/or nitrogen-vacancy defects 325 may remain within the final structures or devices formed and may present issues with performance of final structures or devices.

Method 200 may include performing a treatment operation on the substrate 305 at operation 205. In one embodiment, the treatment operation may include providing a nitrogen-containing precursor to a first processing region of a first semiconductor processing chamber. Nitrogen-containing precursors may be or include any number of nitrogen-containing materials. Accordingly, the nitrogen-containing precursor may be or include diatomic nitrogen (N₂) or ammonia (NH₃), or any other nitrogen-containing material used or useful in semiconductor processing. A hydrogen-containing precursor may also be provided to the region of the semiconductor processing chamber. Hydrogen-containing precursors may be or include any number of hydrogen-containing materials. Accordingly, the hydrogen-containing precursor may be or include diatomic hydrogen (H₂), as well as any other hydrogen-containing material that may be used or useful in semiconductor processing. For example, in some embodiments, the treatment operation may include providing both N₂ and H₂. The nitrogen-containing precursor and, if present, the hydrogen-containing precursor may also be provided with any number of carrier gases, which may include nitrogen, helium, argon, or other noble, inert, or useful precursors.

The treatment operation may further include forming plasma effluents of the nitrogen-containing precursor and, if present, the hydrogen-containing precursor. The plasma effluents of the nitrogen-containing precursor and, if present, the hydrogen-containing precursor may be formed in the first processing region by, for example, applying a plasma power to the first semiconductor processing chamber or to any one or more components of the first semiconductor processing chamber.

The treatment operation may further include contacting the substrate 305 with the plasma effluents of the nitrogen-containing precursor and, if present, the hydrogen-containing precursor. As illustrated in FIG. 3B, the contacting may remove one or more contaminants from the surface of the substrate 305 and/or the surface of the layer of nitrogen-containing material 310. As illustrated in FIG. 3C, the contacting may nitride the surface of the substrate 305 and/or the surface of the layer of nitrogen-containing material 310. Specifically, the contacting may introduce nitrogen terminations 330 to the surface of the substrate 305 and/or the surface of the layer of nitrogen-containing material 310. The removal of one or more contaminants from the surface of the substrate 305 and/or the surface of the layer of nitrogen-containing material 310 may reduce surface traps that may exist in the final structures or devices, such as in high-electron-mobility transistors (HEMTs). By removing the one or more contaminants and therefore reducing surface traps, ON resistance during switching operations may be reduced and performance may be increased. By nitriding the surface, a subsequent deposition, such as a deposition of dielectric material, may uniformly deposit on the surface without the inclusion of any unwanted material, such as the removed contaminants.

In another embodiment, the treatment operation at operation 205 may include providing an aluminum-containing precursor to the first processing region of the first semiconductor processing chamber. Aluminum-containing precursors may be or include any number of aluminum-containing materials. Accordingly, the aluminum-containing precursor may be or include trimethylaluminum (TMA) or dimethylaluminum isopropoxide (DMAI), or any other aluminum-containing material used or useful in semiconductor processing. The aluminum-containing precursor may also be provided with any number of carrier gases, which may include nitrogen, helium, argon, or other noble, inert, or useful precursors.

In embodiments, the aluminum-containing precursor may be used to soak the substrate 305. Accordingly, a plasma may not be generated, and the aluminum-containing precursor may be used as a thermal process instead of a plasma-enhanced process. Therefore, the first processing region of the first semiconductor processing chamber may be maintained plasma-free while contacting the substrate 305 with the aluminum-containing precursor. The contacting may form a layer of aluminum-and-nitrogen-containing material (not shown) on the substrate 305.

Aluminum may be combined with oxygen and/or nitrogen present on the substrate 305 to form aluminum-and-oxygen-containing complexes, aluminum-and-nitrogen-containing complexes, and/or aluminum-oxygen-and-nitrogen-containing complexes. These complexes may be cleaner than the exposed dangling bonds and other lattice distortions that could function as electron traps. Additionally, these complexes may serve as a base for subsequently deposited bulk material as further discussed below. Finally, these complexes may allow the subsequently deposited bulk material to be of higher quality.

In embodiments, contacting or soaking the substrate 305 with the aluminum-containing precursor may be performed cyclically with a purge. For example, a first period of time may include contacting the substrate 305 with the aluminum-containing precursor. The first period of time may be less than or about 30 seconds, and may be less than or about 25 seconds, less than or about 20 seconds, less than or about 15 seconds, less than or about 10 seconds, less than or about 5 seconds, less than or about 1 second, less than or about 0.5 seconds, or less. A second period of time may include a purge with N₂, for example, to remove the aluminum-containing precursor. The second period of time may be greater than or about 1 second, and may be greater than or about 5 seconds, greater than or about 10 seconds, greater than or about 15 seconds, greater than or about 20 seconds, greater than or about 25 seconds, or more. In embodiments, the second period of time may be greater than the first period of time.

A temperature while contacting the substrate 305 with the aluminum-containing precursor may be less than or about 450° C., and may be less than or about 400° C., less than or about 350° C., less than or about 300° C., less than or about 250° C., less than or about 200° C., less than or about 150° C., or less.

In some embodiments, individual operations of the treatment operation may be repeated, such as with different precursors. Specifically, during a first period of time, the substrate 305 may be contacted with a first precursor. After the first period of time, the substrate 305 may then be contacted with a second precursor different from the first precursor. Additionally, the treatment operation may include performing only a nitrogen-containing plasma treatment or only an aluminum-containing precursor treatment. However, some embodiments may include performing both a nitrogen-containing plasma treatment and an aluminum-containing precursor treatment.

Subsequent to removing one or more contaminants and/or nitriding the surface of the substrate 305 and/or the surface of the layer of nitrogen-containing material 310, method 200 may include transferring the substrate 305 from the first processing region of the first semiconductor processing chamber to a second processing region of a second semiconductor processing chamber at operation 210. The substrate 305 may be transferred using means such as robots 126 and/or 128 discussed with regard to FIG. 1. A vacuum environment may be maintained while transferring the substrate 305 from the first processing region of the first semiconductor processing chamber to the second processing region of the second semiconductor processing chamber. By maintaining the vacuum environment, any chance of recontamination, such as through reoxidation, may be reduced and/or prevented.

Once in the second processing region, method 200 may include providing one or more deposition precursors to the second processing region of the second semiconductor processing chamber at operation 215. The one or more deposition precursors may include any number of precursors used or useful for forming dielectric materials. In embodiments, the one or more deposition precursors may include, but are not limited to, an aluminum-containing precursor, a silicon-containing precursor, a nitrogen-containing precursor, an oxygen-containing precursor, or combinations thereof. Aluminum-containing precursors may be or include any number of aluminum-containing materials. Accordingly, the aluminum-containing precursor may be or include aluminum chloride (AlCl₃), trimethylaluminum (TMA) (Al(CH₃)₃), aluminum tri-isopropoxide (AIP) (Al(O(CH(CH₃)₂)₃)), aluminum acetylacetonate (Al(C₅H₇O₂)₃), or any other aluminum-containing material used or useful in semiconductor processing. Silicon-containing precursors may be or include any number of silicon-containing materials. Accordingly, the silicon-containing precursor may be or include silane (SiH₄), disilane (Si₂H₆), trisilane (Si₃H₈), or other organosilanes including cyclohexasilanes, silicon tetrafluoride (SiF₄), silicon tetrachloride (SiCl₄), dichlorosilane (SiH₂Cl₂), or any other silicon-containing material used or useful in semiconductor processing. Nitrogen-containing precursors may be or include any number of nitrogen-containing materials. Accordingly, the nitrogen-containing precursor may be or include diatomic nitrogen (N₂), nitrous oxide (N₂0), nitrogen dioxide (NO₂), ammonia (NH₃), diazene (N₂H₂), or any other nitrogen-containing material used or useful in semiconductor processing. Oxygen-containing precursors may be or include any number of oxygen-containing materials. Accordingly, the oxygen-containing precursor may be or include diatomic oxygen (O₂), ozone (O₃), nitrous oxide (N₂0), nitrogen dioxide (NO₂), or any other oxygen-containing material used or useful in semiconductor processing. The one or more deposition precursors may also be provided with any number of carrier gases, which may include nitrogen, helium, argon, or other noble, inert, or useful precursors.

At optional operation 220, method 200 may include forming plasma effluents of the one or more deposition precursors. The plasma effluents of the one or more deposition precursors may be formed in the second processing region by, for example, applying a plasma power to the second semiconductor processing chamber or to any one or more components of the second semiconductor processing chamber.

Method 200 may include contacting the substrate 305 with the one or more deposition precursors or plasma effluents thereof at operation 225. As illustrated in FIG. 3D, the contacting may deposit a layer of material 335 on the substrate 305. In embodiments, the layer of material 335 may be a passivation material, such as a dielectric material. Depending on the precursors provided at operation 215, the layer of material may include an aluminum-and-nitrogen-containing material, an aluminum-and-oxygen-containing material, a silicon-and-nitrogen-containing material, or a silicon-and-oxygen-containing material. In embodiments, it is contemplated that a multi-layer stack of two or more dielectric materials may be deposited. For example, a first layer of an aluminum-and-nitrogen-containing material may be deposited followed by a second layer of a silicon-and-oxygen-containing material. While some embodiments of the present technology may include forming plasma effluents of the one or more deposition precursors, other embodiments may include plasma-free or thermal-based deposition operations. Accordingly, the layer of dielectric material may be deposited via chemical vapor deposition (CVD), physical vapor deposition (PVD), or atomic layer deposition (ALD). However, any other deposition methods may be used.

The present technology may remove contaminants, such as contamination resulting from oxidation, prior to depositing a passivation material, such as a dielectric material. By removing the contamination, which may include oxygen, carbon, or nitrogen-vacancy defects, the subsequent deposition of the passivation material may not include contaminants at the interface of the passivation material and the substrate 305 or layer of nitrogen-containing material 310 on the substrate 305. This may increase performance of the final structures or devices. Without the surface preclean to remove contaminants, the presence of oxygen, carbon, or nitrogen-vacancy defects may still impair performance. Specifically, electrons traveling along the interface may become stuck or trapped, reduce current, and degrade device operation and performance. Accordingly, the present embodiments may allow for electrons to travel more smoothly and to increase device performance, such as decrease ON resistance during switching.

In some conventional technologies, a single chamber may be used for both contamination removal and passivation deposition. However, the present technology may perform the two distinct operations in separate chambers on a single mainframe. By performing the operations in separate chambers, especially at high volumes of substrates being processed, reproducibility may be increased, and higher quality final devices may be produced. Further, by performing the operations on a single mainframe, vacuum conditions may be maintained between operations, which may avoid exposure to ambient conditions that may contaminate the substrate after the first operation is completed.

The present technology also encompasses a semiconductor processing system that may be operable to perform method 200. The system may include a first semiconductor processing chamber defining a first processing region, a second semiconductor processing chamber defining a second processing region, and a mainframe connected to both the first semiconductor processing chamber and the second semiconductor processing chamber. The first semiconductor processing chamber and the second semiconductor processing chamber may, for example, be any of semiconductor processing chambers 114, 116, 118, 120, 122, and 124 of FIG. 1. The mainframe may be or include transfer platforms 102 and 104 of FIG. 1, although other portions of multi-chamber processing system 100 of FIG. 1 may be encompassed by the mainframe.

The first semiconductor processing chamber may be operable to perform operation 205 previously described. That is, the first semiconductor processing chamber may be operable to perform a surface cleaning operation or a treatment operation on a substrate. Further, the first semiconductor processing chamber may be operable to perform a surface nitridation operation on the substrate.

The second semiconductor processing chamber may be operable to perform operations 215-225 previously described. That is, the second semiconductor processing chamber is operable to perform a dielectric material deposition operation on the substrate. In embodiments, and as previously discussed, the dielectric material deposition operation may form a silicon-and-nitrogen-containing material, a silicon-and-oxygen-containing material, an aluminum-and-nitrogen-containing material, or an aluminum-and-oxygen-containing material on the substrate.

The mainframe may be operable to receive the substrate prior to providing the substrate to the first processing region of the first semiconductor processing chamber. The substrate received in the mainframe may be contaminated with oxygen, carbon, or nitrogen-vacancy defects. The mainframe is operable to transfer the substrate between the first processing region and the second processing region without breaking a vacuum environment.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either limit of the range, both limits of the range, or neither limit of the range are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a nitrogen-containing precursor” includes a plurality of such precursors, and reference to “the layer of dielectric material” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
performing a treatment operation on a substrate housed within a first processing region of a first semiconductor processing chamber, wherein the treatment comprises:
providing a nitrogen-containing precursor to the first processing region of the first semiconductor processing chamber;
forming plasma effluents of the nitrogen-containing precursor; and
contacting the substrate with the plasma effluents of the nitrogen-containing precursor, wherein the contacting nitrides a surface of the substrate;
transferring the substrate from the first processing region of the first semiconductor processing chamber to a second processing region of a second semiconductor processing chamber;
providing one or more deposition precursors to the second processing region of the second semiconductor processing chamber; and
contacting the substrate with the one or more deposition precursors, wherein the contacting deposits a layer of dielectric material on the substrate.

2. The semiconductor processing method of claim 1, wherein the nitrogen-containing precursor comprises diatomic nitrogen (N₂) or ammonia (NH₃).

3. The semiconductor processing method of claim 1, further comprising:
providing a hydrogen-containing precursor to the first processing region of the first semiconductor processing chamber with the nitrogen-containing precursor.

4. The semiconductor processing method of claim 3, wherein the hydrogen-containing precursor comprises diatomic hydrogen (H₂).

5. The semiconductor processing method of claim 1, wherein the substrate comprises a layer of nitrogen-containing material.

6. The semiconductor processing method of claim 1, wherein, prior to contacting the substrate with plasma effluents of the nitrogen-containing precursor, the substrate is contaminated with oxygen, carbon, or nitrogen-vacancy defects.

7. The semiconductor processing method of claim 1, further comprising:
forming plasma effluents of the one or more deposition precursors.

8. The semiconductor processing method of claim 1, wherein the layer of dielectric material comprises a silicon-and-nitrogen-containing material, a silicon-and-oxygen-containing material, an aluminum-and-nitrogen-containing material, or an aluminum-and-oxygen-containing material.

9. The semiconductor processing method of claim 1, wherein the layer of dielectric material is deposited via chemical vapor deposition (CVD), physical vapor deposition (PVD), or atomic layer deposition (ALD).

10. The semiconductor processing method of claim 1, wherein a vacuum environment is maintained while transferring the substrate from the first processing region of the first semiconductor processing chamber to the second processing region of the second semiconductor processing chamber.

11. A semiconductor processing method comprising:
performing a treatment operation on a substrate housed within a first processing region of a first semiconductor processing chamber, wherein the substrate comprises a layer of nitrogen-containing material, and wherein the treatment comprises:
providing an aluminum-containing precursor to a first processing region of a first semiconductor processing chamber; and
contacting the substrate with the aluminum-containing precursor, wherein the contacting forms a layer of aluminum-and-nitrogen-containing material on the substrate;
transferring the substrate from the first processing region of the first semiconductor processing chamber to a second processing region of a second semiconductor processing chamber;
providing one or more deposition precursors to the second processing region of the second semiconductor processing chamber; and
depositing a layer of passivation material on the layer of aluminum-and-nitrogen-containing material on the substrate.

12. The semiconductor processing method of claim 11, wherein the substrate comprises an aluminum-gallium-and-nitrogen-containing material.

13. The semiconductor processing method of claim 11, wherein the aluminum-containing precursor comprises trimethylaluminum (TMA).

14. The semiconductor processing method of claim 11, wherein the first processing region of the first processing chamber is maintained plasma-free.

15. The semiconductor processing method of claim 11, wherein the one or more deposition precursors comprise an aluminum-containing precursor, a silicon-containing precursor, a nitrogen-containing precursor, an oxygen-containing precursor, or combinations thereof.

16. The semiconductor processing method of claim 11, wherein the passivation material comprises a dielectric material.

17. A semiconductor processing system comprising:
a first semiconductor processing chamber defining a first processing region, wherein the first semiconductor processing chamber is operable to perform a treatment operation on a substrate;
a second semiconductor processing chamber defining a second processing region, wherein the second semiconductor processing chamber is operable to perform a dielectric material deposition operation on the substrate; and
a mainframe connected to both the first semiconductor processing chamber and the second semiconductor processing chamber, wherein the mainframe is operable to transfer the substrate between the first processing region and the second processing region without breaking a vacuum environment.

18. The semiconductor processing system of claim 17, wherein the first semiconductor processing chamber is further operable to perform a surface nitridation operation on the substrate.

19. The semiconductor processing system of claim 17, wherein the dielectric material deposition operation forms a silicon-and-nitrogen-containing material, a silicon-and-oxygen-containing material, an aluminum-and-nitrogen-containing material, or an aluminum-and-oxygen-containing material on the substrate.

20. The semiconductor processing system of claim 17, wherein the mainframe is operable to receive the substrate prior to providing the substrate to the first processing region of the first semiconductor processing chamber, wherein the substrate received in the mainframe is contaminated with oxygen, carbon, or nitrogen-vacancy defects.
